(19) United States
(12) Patent Application Publication
(10) Pub. No.: US 2006/0086959 A1
(43) Pub. Date: Apr. 27, 2006

(54) Semiconductor device

(76) Inventor: Seiichi Iwasa, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/257,053

(22) Filed: Oct. 25, 2005

(30) Foreign Application Priority Data
Oct. 26, 2004 (JP) 2004-311305

(51) Int. Cl. H01L 21/8242; H01L 29/94

(52) U.S. Cl. 257/301; 438/243

(57) ABSTRACT

There is provided a semiconductor device including a semiconductor substrate which has an element region in which a diffusion layer for a source or a drain is formed, and a trench for a capacitor, a capacitor dielectric film which is formed on inner surfaces of the trench, a storage electrode which is formed in the trench provide with the capacitor dielectric film, and which has an upper surface lying at a level higher than an upper surface of the diffusion layer, and a conductive connecting part which connects the storage electrode to the diffusion layer and contacts the upper surfaces of the storage electrode and diffusion layer.

### CROSS-REFERENCE TO RELATED APPLICATIONS

This application is based upon and claims the benefit of priority from prior Japanese Patent Application No. 2004-311305, filed Oct. 26, 2004, the entire contents of which are incorporated herein by reference.

### BACKGROUND OF THE INVENTION

1. Field of the Invention

The present invention relates to a semiconductor device.

2. Description of the Related Art

As the components of semiconductor memories become smaller and the integration density of each memory proportionally increases, it is more difficult to secure capacitance of each capacitor for storing electric charge. In view of this, it has been proposed to use trench capacitors that are formed by using the trenches made in the substrate of a semiconductor memory (see, for example, Jpn. Pat. Appln. Kokai Publication No. 7-58217). A trench capacitor is formed, utilizing the sides of a trench. Hence, the trench capacitor can have large capacitance even though it occupies but a small area.

The trench capacitor comprises a capacitor dielectric film and a storage electrode. The capacitor dielectric film is formed on the inner surface of a trench made in a semiconductor substrate. The storage electrode is formed in the trench, provided with the capacitor dielectric film. Adjacent to the trench there is provided an element region. In the element region, diffusion layers are formed, one for a source and the other for a drain. These diffusion layers are connected to the storage electrode, by a conductive connector that is formed in a contact hole made in the substrate.

The storage electrode of the conventional trench capacitor described above has its upper surface positioned below the upper surface of the diffusion layer for a source or drain. The lower surface of the conductive connector therefore lies below (or deeper than) the upper surface of the diffusion layer by at least distance d between the upper surface of the storage electrode and that of the diffusion layer. If the conductive connector is made of polysilicon, the impurities contained in polysilicon diffuse, inevitably increasing the depth of the diffusion layer for a source or drain. The conductive connector may be made of metal. In this case, too, the depth of the diffusion layer increases because it must be set in accordance with the position at which the lower surface of the conductive connector lies.

Thus, the diffusion layer for a source or drain is deep in the conventional trench capacitor. This inevitably degrades the characteristics or reliability of the semiconductor device.

### BRIEF SUMMARY OF THE INVENTION

A semiconductor device according to an aspect of the present invention comprises: a semiconductor substrate which has an element region in which a diffusion layer for a source or a drain is formed, and a trench for a capacitor; a capacitor dielectric film which is formed on inner surfaces of the trench; a storage electrode which is formed in the trench provide with the capacitor dielectric film, and which has an upper surface lying at a level higher than an upper surface of the diffusion layer; and a conductive connecting part which connects the storage electrode to the diffusion layer and contacts the upper surfaces of the storage electrode and diffusion layer.

### BRIEF DESCRIPTION OF THE SEVERAL VIEWS OF THE DRAWING

FIGS. 1 to 13 are sectional views, schematically representing the steps of manufacturing a semiconductor device according to an embodiment of this invention; and

FIG. 14 is a plan view schematically showing the positional relation of the patterns according to the embodiment of the invention.

### DETAILED DESCRIPTION OF THE INVENTION

An embodiment of this invention will be described, with reference to the accompanying drawings.

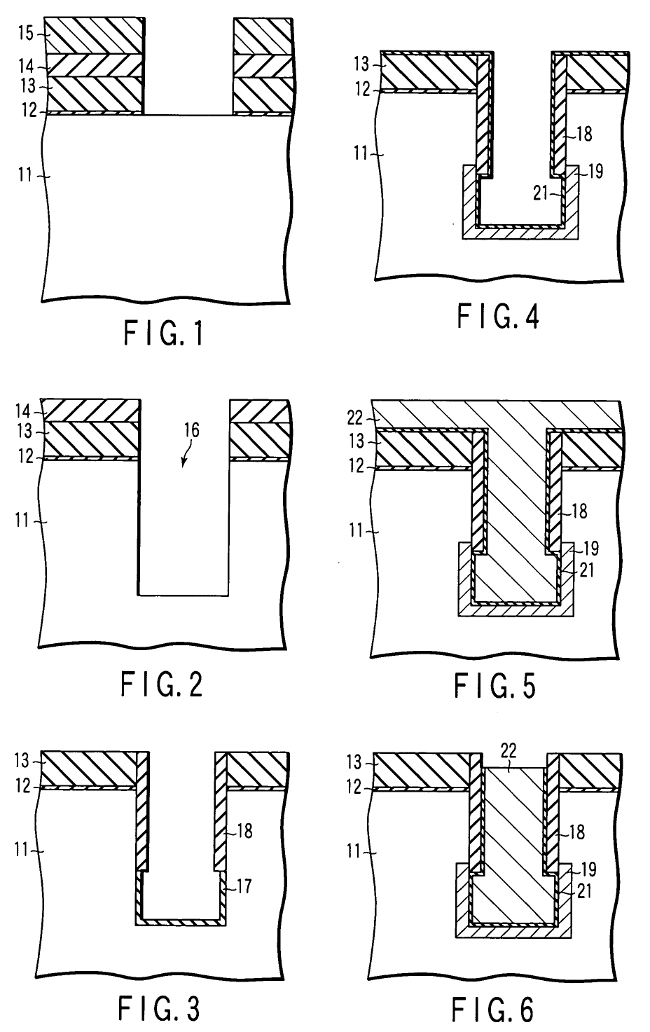

FIGS. 1 to 13 are sectional views illustrating a method of manufacturing a semiconductor device that is an embodiment of this invention. More precisely, the semiconductor device is a dynamic random access memory (DRAM) having a trench capacitor.

First, as shown in FIG. 1, a silicon oxide film 12 about 2 nm thick is formed on a semiconductor substrate 11 such as a silicon substrate by means of thermal oxidation. Next, a silicon nitride film 13 about 200 nm thick is formed on the silicon oxide film 12, by means of chemical vapor deposition (CVD). The silicon nitride film 13 functions as a stopper in the reactive ion etching (RIE) or chemical mechanical polishing (CMP), which will be described later. Then, a silicon oxide film 14 about 1500 nm thick is formed on the silicon nitride film 13 by means of low pressure CVD. Photolighography is carried out, forming a resist pattern 15 that will be used to form a trench pattern. Using the resist pattern 15 as mask, RIE is performed, thereby etching the silicon oxide film 14, silicon nitride film 13 and silicon oxide film 12.

As FIG. 2 shows, the resist pattern 15 is removed. Thereafter, the semiconductor substrate 11 is etched by means of RIE using the silicon oxide film 14 as mask. A trench 16 is thereby made to a depth of about 6 μm in the semiconductor substrate 11. In the trench 16, a capacitor will be formed as will be described later.

As FIG. 3 depicts, the silicon oxide film 14 is removed by application of solution of hydrofluoric acid. Subsequently, low pressure CVD is carried out, forming a silicon nitride film 17 to a thickness of about 10 nm, on the entire surface of the resultant structure. Then, the silicon nitride film 17 is removed, except for the part that lies on the lower part of the trench 16. Using this part of the silicon nitride film 17 as mask, thermal oxidation is performed, thus forming a silicon oxide film 18 about 30 nm thick, on the sides of the trench 16.

As FIG. 4 shows, hot solution of phosphoric acid is applied, removing the silicon nitride film 17. Using the silicon oxide film 18 as mask, vapor phase diffusion is performed. Thus, n-type impurities are introduced into the silicon substrate 11, forming a diffusion layer 19. The diffusion layer 19 will be processed into the plate electrode of the trench capacitor. A capacitor dielectric film 21 is formed on the entire surface of the resultant structure. More specifically, a silicon nitride film about 5 nm thick is first formed by low pressure CVD and an oxide film about 1 nm thick is then formed by thermal oxidation, thereby forming the capacitor dielectric film 21.

Subsequently, low pressure CVD is carried out, forming a polysilicon film 22 on the entire surface of the resultant structure, as is illustrated in FIG. 5. This polysilicon film 22 has a thickness of about 300 nm and contains arsenic (As), i.e., n-type impurities. The polysilicon film 22 will be processed into the storage electrode of the trench capacitor.

As FIG. 6 depicts, RIE is performed, thus etching the polysilicon film 22. More precisely, this etching is so performed that the upper surface of the polysilicon film 22 comes to lie above the upper surface of the semiconductor substrate 11 and below the upper surface of the silicon nitride film 13. Then, solution of hydrofluoric acid is applied, removing the capacitor dielectric film 21 from the upper surface of the silicon nitride film 13 and the top parts of the sides of the silicon oxide film 18.

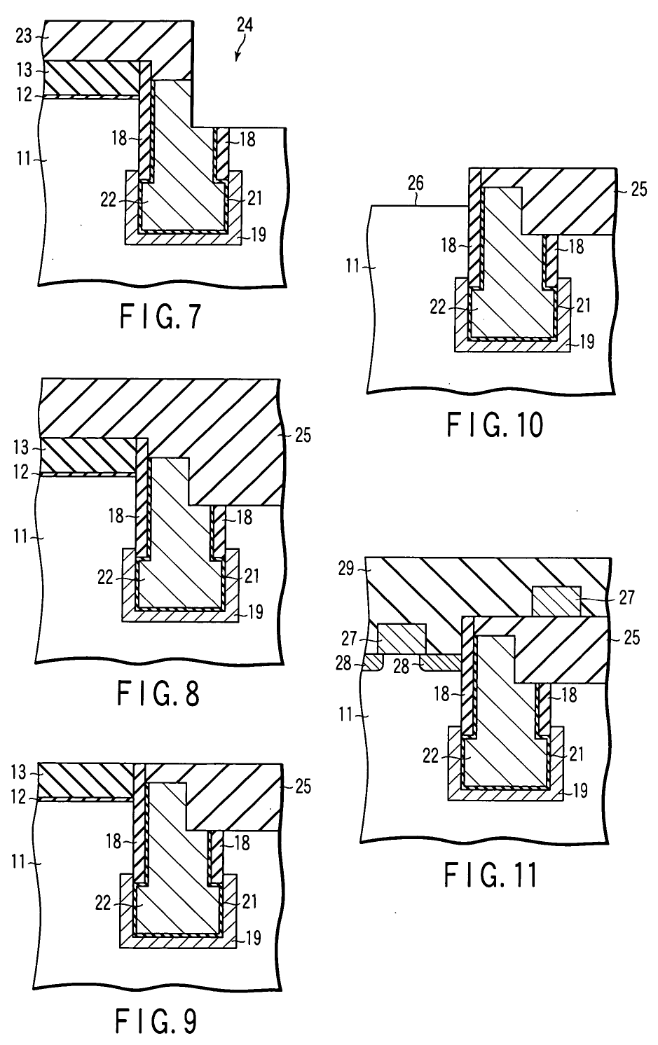

As FIG. 7 shows, low pressure CVD is performed, forming a silicon oxide film 23 on the entire surface of the structure shown in FIG. 6. This silicon oxide film 23 has a thickness of about 400 nm and contains boron (B). The silicon oxide film 23 is patterned. Using the film 23 patterned, as hard mask, RIE is carried out, forming a trench 24 in which an isolation region will be formed.

As FIG. 8 shows, the silicon oxide film 23 is removed by applying solution of hydrofluoric acid. Then, plasma CVD is carried out, forming a silicon oxide film 25 about 500 nm thick as an isolation insulating film, on the entire surface of the resultant structure.

As illustrated in FIG. 9, CMP is performed on the silicon oxide film 25, using the silicon nitride film 13 as stopper. As a result, the silicon oxide film 25 is removed from the silicon nitride film 13. Thus, the upper surface of the silicon oxide film 25 comes to lie at the same level as the upper surface of the silicon nitride film 13. The silicon oxide film 25 remains covering the polysilicon film 22 even after the silicon oxide film 25 has been polished. This is because the polysilicon film 22 has been so formed in the step shown in FIG. 6 that its upper surface lies below the upper surface of the silicon nitride film 13.

As FIG. 10 shows, hot solution of phosphoric acid is applied, removing the silicon nitride film 13. As a result, a trench capacitor is formed, which has the capacitor dielectric film 21 formed in the trench 16, a plate electrode formed of the diffusion layer 19, and a storage electrode formed of the polysilicon film 22. That part of the substrate 11, which is surrounded by the isolation insulting film (i.e., silicon oxide film 25) is used as an element region 26.

As FIG. 11 shows, a gate line 27 is formed. The gate line 27 has an electrode part and a wiring part. The electrode part lies on a gate-insulating film (not shown) that is formed on the semiconductor substrate 11. The wiring part lies on the silicon oxide film 25 that is the isolation region. Thereafter, impurity ions are implanted into the surface of the element region 26. Heat treatment is performed, activating the impurities thus implanted, thereby forming a diffusion layer 28 for a source-drain region. An MIS transistor is thus formed. An interlayer insulating film 29 is then formed, covering the element region 26 and the silicon oxide film 25 (i.e., isolation region).

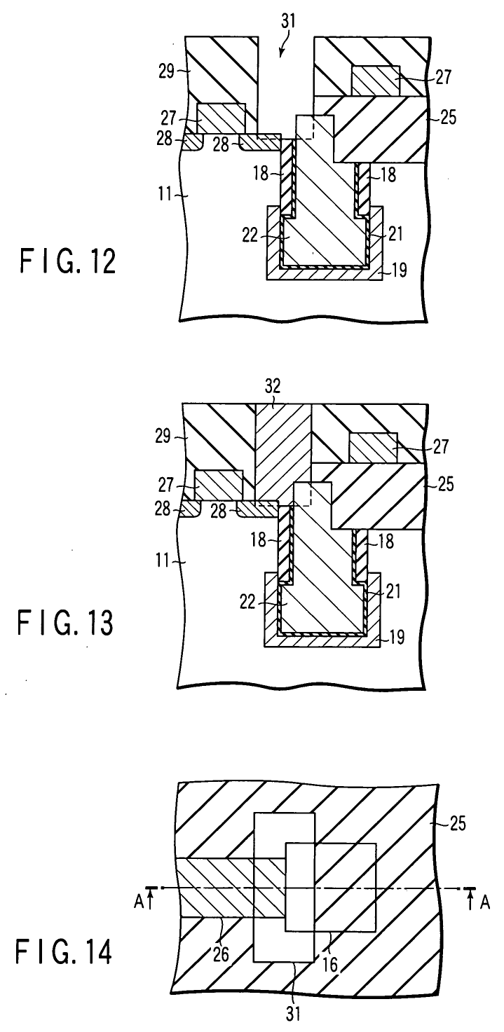

Next, as FIG. 12 depicts, RIE is carried out, making a contact hole 31 so that the polysilicon film 22 (i.e., storage electrode of the trench capacitor) may be connected to the diffusion layer 28 for a source-drain region. To be more specific, parts of the silicon oxide film 25 and interlayer insulating film 29 are removed, thus making the contact hole 31.

FIG. 14 is a plan view, or a schematic representation of the positional relation of the patterns of the trench 16, element region 26 and contact hole 31. A section taken along line A-A in FIG. 14 is represented by the sectional view of FIG. 12. As seen from FIG. 14, the pattern of the contact hole 31 is broader than the pattern of the trench 16 and that of the element region 26. Hence, the pattern of the trench 16 and the pattern of the element region 26 lie, in part, in the pattern of the contact hole 31, and the boundary between the patterns of the element region 26 and trench 16 lies in the pattern of the contact hole 31.

The contact hole 31 needs only to reach the upper surface of the diffusion layer 28. To expose the upper surface of each diffusion layer 28 in a wafer reliably, however, over-etching is carried out. As a result, the silicon oxide film 25 is etched to a level lower than the upper surface of the diffusion layer 28. The bottom of the contact hole 31 therefore lies below the upper surface of the diffusion layer 28, as indicated by the broken line in FIG. 12. Nonetheless, the bottom of the contact hole 31 lies above the lower surface of the diffusion layer 28. In addition, the silicon oxide film 18 formed at the boundary between the storage electrode 22 and the element region 26 is etched to a level lower than the upper surface of the diffusion layer 28. Hence, the sides of the storage electrode 22 and element region 26 are exposed in part in this etching step.

As FIG. 13 shows, low pressure CVD is performed, forming a polysilicon film 32 on the entire surface of the resultant structure. The film 32 contains n-type impurities, such as phosphorus (P) or arsenic (As), and has a thickness of about 300 nm. Then, RIE is performed on the polysilicon film 32, removing that part of the film 32 which lies on the interlayer insulating film 29. The contact hole 31 is thereby filled with the polysilicon film 32. As FIG. 14 depicts, the pattern of the trench 16 and the pattern of the element region 26 lie in part in the pattern of the contact hole 31. The polysilicon film 32 therefore contacts the upper surface of the storage electrode 22 and the upper surface of the element region 26 (i.e., upper surface of the diffusion layer 28). Further, the polysilicon film 32 contacts the sides of the storage electrode 22 and the sides of the element region 26 (i.e., sides of the diffusion layer 28), too. Heat treatment is carried out, activating the n-type impurities contained in the polysilicon film 32. A conductive connector 32 is thereby formed, which connects the storage electrode 22 of the trench capacitor to the diffusion layer 28 that serves either the source or drain of the MIS transistor.

In this embodiment, the upper surface of the storage electrode 22 lies above that of the element region 26 (i.e., the upper surface of the diffusion layer 28). The conductive connector 32 made by processing a polysilicon film can therefore has its lower surface at a higher level than is possible in the conventional semiconductor devices. It is possible to prevent the depth of the diffusion layer 28 from increasing, during the heat treatment performed to activate the impurities contained in the polysilicon film. The depth of the diffusion layer 28 may be set in accordance with the depth of the conductive connector 32 (i.e., the level at which the lower surface of the conductive connector 32 lies). In this case, too, the depth of the diffusion layer 28 can be reduced. Thus, the depth of the diffusion layer for the source or drain can be prevented from increasing. This can suppress the degradation of the characteristics or reliability of the semiconductor device.

In the embodiment described above, the conductive connector 32 is made of polysilicon film containing impurities (i.e., semiconductor film containing impurities). Nevertheless, the conductive connector 32 may be made of any other electrically conductive material. It may be made of, for example, metal such as tungsten (W) or the like. In the embodiment described above, the storage electrode 22 is made of polysilicon film containing impurities (i.e., semiconductor film containing impurities). Instead, the storage electrode 22 may be made of any other conductive material.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate which has an element region in which a diffusion layer for a source or a drain is formed, and a trench for a capacitor;
a capacitor dielectric film which is formed on inner surfaces of the trench;
a storage electrode which is formed in the trench provide with the capacitor dielectric film, and which has an upper surface lying at a level higher than an upper surface of the diffusion layer; and
a conductive connecting part which connects the storage electrode to the diffusion layer and contacts the upper surfaces of the storage electrode and diffusion layer.

2. The semiconductor device according to claim 1, wherein the conductive connecting part is made of semiconductor containing impurities.

3. The semiconductor device according to claim 2, wherein the semiconductor containing impurities includes silicon.

4. The semiconductor device according to claim 1, further comprising an isolation insulating film which surrounds the element region, and an interlayer insulating film which is formed on the element region and the isolation insulating film.

5. The semiconductor device according to claim 4, wherein the upper surface of the storage electrode lies at a level lower than an upper surface of the isolation insulating film.

6. The semiconductor device according to claim 4, wherein the conductive connecting part is formed in a hole that has been made by removing a part of the isolation insulating film and a part of the interlayer insulating film.

7. The semiconductor device according to claim 6, wherein the element region has a pattern, an edge of which partly lies in a pattern of the hole.

8. The semiconductor device according to claim 6, wherein the trench has a pattern, an edge of which partly lies in a pattern of the hole.

9. The semiconductor device according to claim 1, wherein the conductive connecting part contacts a side of the storage electrode and a side of the diffusion layer.

10. The semiconductor device according to claim 1, wherein a pattern of the element region and a pattern of the trench are adjacent to each other.

11. The semiconductor device according to claim 10, wherein a boundary between the pattern of the element region and the pattern of the trench lies in a pattern of the conductive connecting part.

12. The semiconductor device according to claim 1, further comprising an insulating film which is interposed between the diffusion layer and the storage electrode.

13. The semiconductor device according to claim 1, wherein a lowest part of the conductive connecting part lies at a level higher than a lower surface of the diffusion layer.

14. The semiconductor device according to claim 1, further comprising a plate electrode formed in the semiconductor substrate, and wherein the capacitor dielectric film is provided between the storage electrode and the plate electrode.

15. The semiconductor device according to claim 1, which includes a memory device.

16. The semiconductor device according to claim 1, which includes a DRAM.
